(19) United States
(12) Patent Application Publication
(10) Pub. No.: US 2018/0364563 A1
(43) Pub. Date: Dec. 20, 2018

(54) METHOD AND APPARATUS FOR INSPECTING A SAMPLE

(71) Applicant: Applied Materials, Inc., Santa Clara, CA (US)

(72) Inventors: Kulpreet Singh VIRDI, München (DE); Bernhard G. MUELLER, Finsing (DE)

(21) Appl. No.: 15/628,235

(22) Filed: Jun. 20, 2017

(51) Int. Cl. G03F 1/86; G01N 21/956; H01J 37/28; H01J 37/304; H01J 37/244

(52) U.S. Cl. CPC G03F 1/86; G01N 21/95684; H01J 37/28; H01J 2237/18; H01J 37/244; H01J 2237/24475; H01J 37/304

(57) ABSTRACT

A method of inspecting a sample is described which includes a multilevel structure with a first layer that is arranged above a second layer. The method includes: arranging the sample in a vacuum chamber; directing a primary electron beam onto the sample such that first primary electrons of the primary electron beam are backscattered by the first layer to form first backscattered electrons and second primary electrons of the primary electron beam are backscattered by the second layer to form second backscattered electrons; and detecting signal electrons comprising the first backscattered electrons and the second backscattered electrons for obtaining spatial information on both the first layer and the second layer. Further, an apparatus including one or more electron microscopes for inspecting a sample including a multilevel structure is described.

### FIELD

The present disclosure relates to a method for inspecting a sample having a multilevel structure, particularly a large-area substrate for display manufacturing. More particularly, embodiments described herein relate to methods and apparatuses for inspecting samples having a multilevel structure with a first layer arranged at least partially above a second layer, particularly for at least one of imaging, reviewing and inspecting defects of the sample.

### BACKGROUND

In many applications, thin layers are deposited on a substrate, e.g. on a glass substrate. Conventionally, the substrates are coated in vacuum chambers of a coating apparatus. For some applications, the substrates are coated in a vacuum chamber using a vapor deposition technique. Over the last few years, electronic devices and particularly opto-electronic devices have reduced significantly in price. Further, the pixel density in displays has increased. For TFT displays, a high density TFT integration is beneficial. In spite of the increased number of thin-film transistors (TFT) within a device, the yield is to be increased and the manufacturing costs are to be reduced further.

Typically, a plurality of layers is deposited on a substrate such as a glass substrate to form an array of electronic or optoelectronic devices such as TFTs on the substrate. A substrate having a multilevel structure such as a plurality of TFTs formed thereon is also referred to as a “sample” herein.

For the manufacturing of TFT-displays and other multilevel structures, it may be beneficial to inspect the deposited layers to monitor the quality of the sample, particularly the quality of the deposited multilevel structure.

The inspection of the substrate can, for example, be carried out by an optical system. However, the dimension of some of the features of the multilevel structure and the size of defects to be identified may be below the optical resolution, making some of the defects non-resolvable to the optical system. An inspection of small portions of samples has also been carried out using charged particle beam devices, such as electron microscopes. However, only the surface of a sample can typically be inspected with a conventional electron microscope.

Accordingly, given the increasing demand for an increased quality of displays on large area substrates, there is a need for an improved method for quickly and reliably inspecting samples having multilevel structures.

### SUMMARY

According to embodiments, a method of inspecting a sample having a multilevel structure as well as an apparatus for inspecting a sample having a multilevel structure are provided. Further aspects, benefits, and features of the present disclosure are apparent from the claims, the description, and the accompanying drawings.

According to one embodiment, a method of inspecting a sample having a multilevel structure with a first layer that is arranged above a second layer is provided. The method includes: arranging the sample in a vacuum chamber, directing a primary electron beam onto the sample such that first primary electrons of the primary electron beam are backscattered by the first layer to form first backscattered electrons and second primary electrons of the primary electron beam are backscattered by the second layer to form second backscattered electrons, and detecting signal electrons comprising the first backscattered electrons and the second backscattered electrons for obtaining spatial information on both the first layer and the second layer.

In some embodiments, an image providing spatial information on both the first layer and the second layer is generated based on the detected signal electrons.

According to another embodiment, an apparatus for inspecting a sample having a multilevel structure with a first layer that is arranged above a second layer is provided. The apparatus includes: a vacuum chamber, a sample support arranged in the vacuum chamber wherein the sample support is configured to support the sample, and an electron microscope configured to direct a primary electron beam toward the sample such that first primary electrons of the primary electron beam are backscattered by the first layer to form first backscattered electrons and second primary electrons of the primary electron beam are backscattered by the second layer to form second backscattered electrons. The electron microscope includes a detector device configured to detect signal electrons comprising the first backscattered electrons and the second backscattered electrons, and a signal processing device configured to generate an image providing information on both the first layer and the second layer.

According to a further aspect, an apparatus for inspecting a sample having a multilevel structure with a first layer that is arranged above a second layer is provided. The apparatus includes a vacuum chamber, a sample support arranged in the vacuum chamber wherein the sample support is configured to support the sample, and a plurality of electron microscopes for a simultaneous inspection of a plurality of areas of the sample. Each electron microscope is configured to direct a primary electron beam toward the sample such that first primary electrons of the primary electron beam are backscattered by the first layer to form first backscattered electrons and second primary electrons of the primary electron beam are backscattered by the second layer to form second backscattered electrons. The electron microscopes include a detector device configured to detect signal electrons including the first backscattered electrons and the second backscattered electrons, respectively. Further, a signal processing device configured to generate an image containing information on both the first layer and the second layer is provided.

### BRIEF DESCRIPTION OF THE DRAWINGS

A full and enabling disclosure to one of ordinary skill in the art is set forth in the remainder of the specification including reference to the accompanying drawings wherein:

FIG. 1 shows a schematic sectional view of an apparatus for inspecting a sample according to embodiments described herein;

FIG. 2 shows a schematic sectional view of an apparatus for inspecting a sample according to embodiments described herein;

FIG. 3 shows a schematic sectional view of an apparatus for inspecting a sample according to embodiments described herein;

FIG. 4A shows an image of a sample generated according to a method described herein;

FIG. 4B shows an image of a sample generated according to a conventional method; and

FIG. 5 is a flow diagram illustrating a method for inspecting a sample according to embodiments described herein.

### DETAILED DESCRIPTION

Reference will now be made in detail to the various exemplary embodiments, one or more examples of which are illustrated in each figure. Each example is provided by way of explanation and is not meant as a limitation. For example, features illustrated or described as part of one embodiment can be used on or in conjunction with other embodiments to yield yet further embodiments. The intention is that the present disclosure includes such modifications and variations.

Within the following description of the drawings, the same reference numbers refer to the same components. Only the differences with respect to the individual embodiments are described. The structures shown in the drawings are not necessarily depicted true to scale but rather serve the better understanding of the embodiments.

The term “sample” as used herein embraces substrates with a multilevel structure formed thereon. The substrates may be inflexible substrates, e.g., a glass substrate or a glass plate, or flexible substrates, such as a web or a foil. The sample may be a coated substrate, wherein one or more thin layers of materials are coated or deposited on the substrate, for example by a physical vapor deposition (PVD) process or a chemical vapor deposition process (CVD). In particular, the sample may be a substrate for display manufacturing having a plurality of electronic or optoelectronic devices formed thereon. The electronic or optoelectronic devices formed on the substrate are typically thin film devices including a stack of thin layers. For example, the sample may be a substrate with an array of thin film transistors (TFTs) formed thereon, e.g. a thin film transistor based substrate.

Embodiments described herein relate to the inspection of a sample, wherein the sample includes a multilevel structure which may be formed on a substrate. The multilevel structure may include electronic or optoelectronic devices such as transistors, particularly thin film transistors. The substrate may be a large area substrate, particularly a large area substrate for display manufacturing.

According to some embodiments, large area substrates may have a size of at least 1 m². The size may be from about 1.375 m² (1100 mm×1250 mm—GEN 5) to about 9 m², more specifically from about 2 m² to about 9 m² or even up to 12 m². For instance, a large area substrate can be GEN 5, which corresponds to about 1.375 m² substrates (1.1 m×1.25 m), GEN 7.5, which corresponds to about 4.39 m² substrates (1.95 m×2.25 m), GEN 8.5, which corresponds to about 5.7 m² substrates (2.2 m×2.5 m), or even GEN 10, which corresponds to about 9 m² substrates (2.88 m×3130 m). Even larger generations such as GEN 11 and GEN 12 and corresponding substrate areas can similarly be implemented.

Regular process control may be beneficial in the production of flat panels, displays, OLED devices such as OLED screens, TFT based substrates and other samples including a plurality of electronic or optoelectronic devices formed thereon. Process control may include regular monitoring, imaging and/or inspection of certain critical dimensions as well as defect review. The dimensions may relate to features which lie below a top layer of a multilevel structure. In particular, it may be beneficial to inspect features lying below a passivation layer.

However, the inspection of features of deep layers or buried layers may be difficult, since most inspection techniques focus on the inspection of a top surface of a sample. For example, the usage of secondary electrons (SE) for the inspection of buried layers may not be possible because the secondary electron signal typically stems from a sample depth of only a few nm from the top surface of the sample and as such cannot image features which lie beneath this depth. In particular, electron microscopes which utilize secondary electrons for the inspection of a sample are typically not usable for the inspection of features which at least partially lie deeper than within a depth of a few nm.

“Secondary electrons” (SE) as used herein may be understood as low energy (<50 eV) electrons generated and emitted by the sample when hit by a primary charged particle beam such as a primary electron beam. Secondary electrons may provide information about the geometry and spatial characteristics of the sample surface, such that the secondary electron signal of a scanning electron microscope (SEM) may be used for generating an image of the sample surface. Secondary electrons are typically emitted from within a few nm of the sample surface and a majority of the secondary electrons has an energy in the range of a few eV up to about 10 eV, particularly less than 50 eV. Secondary electrons may be generated when a primary electron transfers energy to a “free” (loosely bound) electron of the sample material. Metallic layers with numerous free electrons typically emit a large amount of SEs.

“Backscattered electrons” (B SE) as used herein may be understood as electrons which have been scattered or reflected by atoms of the sample upon impingement on the sample. In particular, primary electrons of a primary electron beam may impinge on a sample and may be scattered back elastically or inelastically by the atoms of the sample. Typically, the energy of the backscattered electrons is in the range of more than 1 keV, e.g. several keV up to 10 keV or more, depending on the energy of the primary electrons. In the case of an elastic scattering process, the energy of the backscattered electrons may essentially correspond to the energy of the incoming primary electrons.

Due to the high electron energy of the backscattered electrons, backscattered electrons may be capable of escaping from deeper layers of a sample. Accordingly, backscattered electrons may be utilized for gaining spatial information about deeper layers or buried layers of a substrate, e.g. layers located from tens of nanometers up to hundreds of nanometers or even more below the sample surface. According to embodiments described herein, an image of the sample is generated based on the backscattered electron signal, such that the image may provide information not only about the top layer of the sample, but also about deeper layers.

Heavy elements backscatter electrons more strongly than light elements. Accordingly, sample areas including heavy elements appear brighter in the image than areas including light elements. For that reason, backscattered electrons may be used to detect and differentiate areas of a sample including different chemical compositions.

According to embodiments described herein, backscattered electrons are utilized to inspect layers of different chemical compositions arranged at least partially on top of each other. In particular, backscattered electrons are utilized to gain insight into a multilevel structure having a first layer and a second layer, wherein the first layer is arranged above the second layer. A particularly simple and time-saving method is described for inspecting and imaging samples with multilevel structures, utilizing an electron microscope configured to detect backscattered electrons.

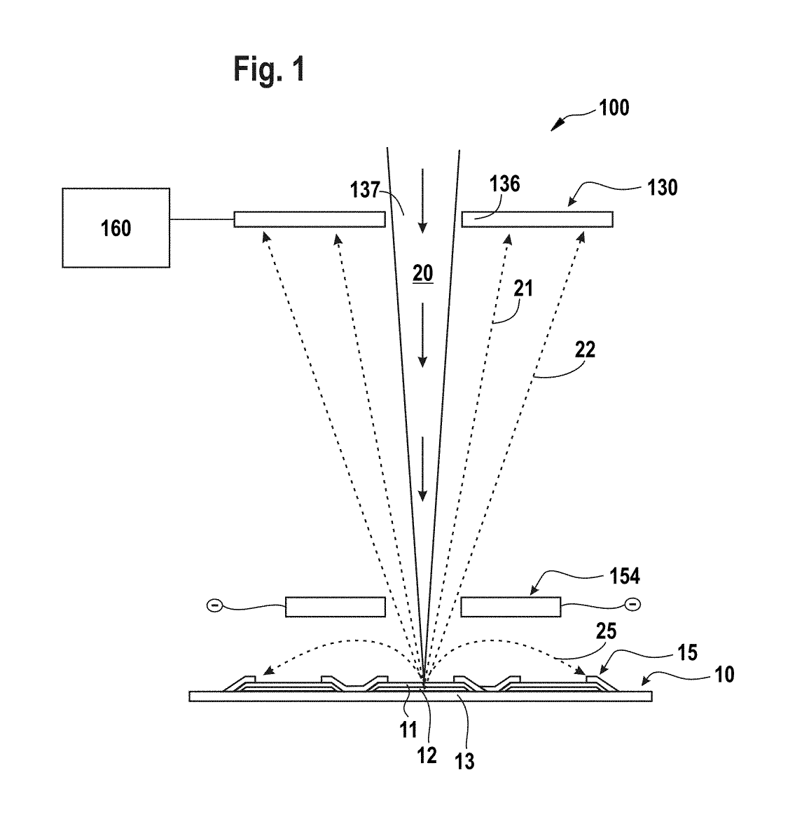

FIG. 1 is a schematic sectional view of an apparatus 100 for inspecting a sample 10 according to embodiments described herein. The sample 10 has a multilevel structure 15 with a first layer 11 that is arranged above a second layer 12. In some embodiments, the multilevel structure 15 may have three, four, five or more layers which may be arranged at least partially on top of each other. For example, the multilevel structure 15 may be an array of electronic devices such as thin film transistors deposited on a substrate, e.g. a large area substrate for display manufacturing.

The method according to embodiments includes arranging the sample 10 in a vacuum chamber (not depicted in FIG. 1), and directing a primary electron beam 20 toward the sample 10 such that the primary electron beam 20 impinges on the sample 10. For example, the primary electron beam 20 may be focused on the sample by an objective lens. The primary electron beam 20 is directed onto the sample 10 such that first primary electrons of the primary electron beam 20 are backscattered by the first layer 11 to form first backscattered electrons 21 and second primary electrons of the primary electron beam are backscattered by the second layer 12 to form second backscattered electrons 22. Typically, the first backscattered electrons 21 and the second backscattered electrons 22 are reflected back from the sample in a backward direction essentially opposite to the incoming direction of the primary electron beam 20, e.g. at a small reflection angle of 30° or less.

Thereupon, signal electrons which include the first backscattered electrons 21 and the second backscattered electrons 22 are detected by a detector device 130 for obtaining spatial information about both the first layer 11 and the second layer 12. The first backscattered electrons 21 and the second backscattered electrons 22 may be detected simultaneously by a detector device, i.e. in a one-stage acquisition process. In particular, the detector signal may be processed by a signal processing device 160 which may be configured to generate an image of at least an area of the sample 10 based on the detector signal. Alternatively or additionally, the signal processing device 160 may be configured to identify defects, to measure distances and dimensions and/or to inspect features such as edges of both the first layer 11 and the second layer 12 based on the detector signal.

The signal electrons which are detected by the detector device 130 include both the first backscattered electrons 21 reflected by the first layer 11 and the second backscattered electrons 22 reflected by the second layer 12. In some embodiments, the signal electrons detected by the detector device 130 may include yet further backscattered electrons scattered from one or more further layers. Accordingly, the detector signal provides spatial information about both the first layer 11 and the second layer 12, such that both the first layer 11 and the second layer 12 may be inspected based on the detector signal.

According to embodiments described herein, the parameters of the primary electron beam 20 are selected such that first backscattered electrons 21 and second backscattered electrons 22 are emitted from the sample 10. In particular, the electron energy of the primary electron beam is selected such that at least some primary electrons of the primary electron beam 20 penetrate the sample 10 through to the second layer 12. For example, the landing energy of the primary electron beam 20 impinging on the sample may be set such that at least a portion of the primary electrons penetrates at least the first layer 11 and is scattered back by the second layer 12. In particular, the landing energy of the primary electron beam 20 on the sample may be 5 keV or more, particularly 10 keV or more, more particularly 30 keV or more, or even 50 keV or more. In some embodiments, the landing energy of the primary electron beam 20 on the sample may be below 5 keV, e.g. from 1 keV to 5 keV, such as about 3 keV. The landing energy may be selected depending on the characteristics of the layer stack to be inspected, e.g. depending on the number and the thickness of the layers.

In some embodiments, the position of the sample and the dimension of the focal point of the primary electron beam 20 may be set such that first backscattered electrons 21 and second backscattered electrons 22 are emitted by the sample 10 and detected by the detector device 130 with a high efficiency, while at the same time providing an adequate spatial resolution. Yet further, the brightness of the primary electron beam may be selected as appropriate.

According to embodiments described herein, a single-stage acquisition process is utilized for gaining spatial insight in two or more layers of a multilevel structure arranged on top of each other. In other words, the signal electrons simultaneously scattered by the sample upon impingement of one primary electron beam are utilized for inspecting a layer stack including two or more layers. According to the method described herein, it may not be necessary to firstly collect information on the first layer by detecting electrons of a first primary beam scattered by the first layer, and to subsequently collect information on the second layer by detecting electrons of a second primary beam scattered by the first layer, wherein the subsequently collected information may then be processed in one image. Rather, information on both the first layer 11 and the second layer 12 is collected at the same time upon the impingement of one primary beam. In particular, an image of the sample may be generated based on the information acquired in a single acquisition stage. Information on the topology and geometry of underlying features of a second layer can be gained without any spectroscopic method such as energy dispersive spectroscopy (EDS). Rather, the material contrast between the first and second layers may be directly visible from the image generated based on the electron signal.

The method described herein is based on the finding that multilevel structures formed on substrates for display manufacturing typically include a plurality of spatial features such as edges, steps, holes, openings, recesses, overlaps and/or undercuts of the first layer 11 and the second layer 12, where the overlay between the first layer 11 and the second layer 12 changes locally. Further, the first layer 11 and the second layer 12 include different materials with different atomic numbers with different backscattering capabilities. Accordingly, regions of changing overlay between the first layer 11 and the second layer 12 will appear as regions of a specific change of brightness in the detector signal and in the image that is generated therefrom, respectively.

In a first example, an opening may be formed in the second layer, but not in the first layer, at a specific location. The second layer may be made of a heavy material with a high electron backscattering capability. In an image generated on the basis of signal electrons including the first backscattered electrons and the second backscattered electrons, the opening in the second layer may appear as a region of reduced brightness such that a dimension of the opening can be measured.

In a second example, the first layer 11 and the second layer 12 should ideally have a corresponding edge forming an end of both the first layer and the second layer. However, in the actual sample, there may be an undercut, such that the second layer ends before the first layer. In the image generated based on the signal electrons including the first backscattered electrons and the second backscattered electrons, said edge area may appear as at least three regions of different brightness which may allow for a measurement of a width of the undercut. In particular, an area where the first layer and the second layer are arranged above each other may have a brightness in the generated image that is different from the brightness of an area where only the first layer is present.

The ideal geometry and topology of the multilevel structure may be previously known. Accordingly, by comparing the ideal geometry with the geometry in an image generated based on the detector signal, defect review, metrology and inspection of features of the first layer and the second layer is possible based on the information collected in a single-stage acquisition process.

According to some embodiments described herein, an area of the sample 10 is scanned one single time with the primary electron beam 20, and an image of said area is generated based on the signal electrons detected during said scan. The generated image may provide spatial information on both the first layer 11 and the second layer 12. For example, features of the generated image may be compared with corresponding features of an ideal topology, in order to identify defects of the sample.

According to embodiments, which may be combined with other embodiments described herein, the method may include generating an image of the multilevel structure 15 based on the detected signal electrons, wherein the image includes spatial information about both the first layer 11 and the second layer 12. A scanning deflector arrangement may be provided for scanning the primary electron beam 20 over the sample.

Alternatively or additionally, the method may include inspecting the first layer 11 and the second layer 12, particularly inspecting a quality of an edge of at least one or both of the first layer 11 and the second layer 12. In some embodiments, the first layer 11 and the second layer 12 may be inspected automatically, e.g. by an automatic measurement of dimensions of specific features of buried layers or by an automatic comparison of measured dimensions and dimensions of an ideal topology of the multilayer structure.

Alternatively or additionally, the method may include reviewing, analyzing and/or identifying defects of at least one or both of the first layer 11 and the second layer 12.

Alternatively or additionally, the method may include measuring distances or dimensions of at least one or both of the first layer 11 and the second layer 12. For example dimensions of features of buried layers or deep layers of the multilevel structure may be measured.

Alternatively or additionally, the method may include performing an overlay metrology, e.g. including inspecting an edge quality of the first layer and the second layer.

In some embodiments, which may be combined with other embodiments described herein, the multilevel structure 15 has three, four, five or more layers which are arranged at least partially on top of each other. For example, the multilevel structure 15 may include an array of thin film electronic devices which include three or more layers, respectively. The three or more layers may be at least partially made of different materials having different atomic numbers, i.e. different Z numbers.

For example, one or more layers of the three or more layers may be a metal layer, e.g. a copper layer or a silver layer. Alternatively or additionally, at least one layer of the three or more layers may be a transparent conductive oxide layer (TCO layer), e.g. an ITO layer. Alternatively or additionally, at least one layer of the three or more layers may be a dielectric layer, e.g. an insulating dielectric layer. For example, a dielectric layer may be at least partially arranged between two conductive layers of the multilevel structure. In some embodiments, at least one semiconductor layer may be provided.

In some embodiments, respective primary electrons of the primary electron beam 20 are scattered by each of the three or more layers of the multilevel structure 15 and detected by the detector device 130 for obtaining spatial information on each of the three or more layers, particularly in a single-stage acquisitions process.

For example, in some embodiments, an image may be generated based on signal electrons comprising first backscattered electrons 21 backscattered by the first layer 11, second backscattered electrons 22 backscattered by the second layer 12, third backscattered electrons backscattered by a third layer at least partially arranged below the second layer, and optionally fourth or further backscattered electrons backscattered by a fourth or further layer arranged at least partially below the third layer. Said first, second, third, and further backscattered electrons may correspond to scattered portions of one single primary electron beam impinging on the sample. Accordingly, an image containing spatial information on a plurality of layers of a multilevel substrate can be formed based on the detector signal in a single-stage acquisition process, e.g. by scanning the sample one single time.

In some embodiments, the inspected sample may include a large-area substrate 13 for display manufacturing, wherein the multilevel structure 15 is formed on the sample, e.g. by one or more deposition techniques. The substrate may have a size of 1 m² or more, particularly 5 m² or more. Accordingly, the vacuum chamber in which the method described herein is performed may include a substrate support configured for supporting a large-area substrate 13 having a size of 1 m² or more, particularly 5 m² or more. In particular, the vacuum chamber may be big enough to hold and inspect the complete sample to be imaged by detecting the backscattered electrons.

The multilevel structure 15 may include a plurality of multilevel electronic or optoelectronic devices such as transistors, particularly TFTs. In some embodiments, the sample may be or include at least one of a glass panel, a display panel, an LCD screen, a TFT screen, and an OLED display.

The apparatus 100 may be an in-line inspection apparatus including an electron microscope configured for in-line inspection of samples during manufacturing, e.g. subsequent to the formation of the multilevel structure on a substrate. For example, the electron microscope 200 may be arranged in a vacuum system that is configured to deposit one or more layers on a substrate, e.g. in an inspection chamber which may be arranged downstream from a deposition chamber.

The electron microscope may be a scanning electron microscope (SEM) configured to scan the sample and to generate an image of at least an area of the sample based on the detector signal.

In some embodiments, the multilevel structure 15 may include multilevel features with nonlinear or curved edges, wherein the nonlinear or curved edges are imaged or inspected. For example, the method described herein may be suitable for imaging and inspecting curved features, irregular features, round features and other nonlinear features of buried layers which may be arranged below a top layer.

According to embodiments, which may be combined with other embodiments described herein, the multilevel structure 15 may include a passivation layer. The passivation layer may be an upper layer arranged above one or more buried layers. For example, the passivation layer may be a protection layer or shielding layer. At least the second layer 12 (or both the first and second layers) may be arranged below the passivation layer. Accordingly, insight can be gained into the spatial characteristics of layers arranged below a passivation layer. In particular, at least one of the first layer 11 and the second layer 12 may be arranged on either the array, the backplane, or the front-plane of a TFT-based display panel or a substrate used in the manufacture of a TFT-based display panel. For example, in the case of an OLED display, at least one of the array (backplane) and the front-plane may be inspected according to method described herein.

The first layer 11 may include a first material having a first atomic number with a first electron backscattering capability, and the second layer 12 may include a second material having a second atomic number with a second electron backscattering capability. For example, the Z-number of the first material and the Z-number of second material may differ by more than 10, particularly by more than 20.

The method may further include generating an image based on the detected signal electrons, wherein holes, openings, steps, recesses, overlaps and/or undercuts of at least one of the first layer and the second layer appear as regions of specific brightness in the image, respectively.

In some embodiments, the first layer 11 may include a first material having a first atomic number. Material residues made of a second material having a second atomic number different from the first atomic number may be arranged below the first layer. Such material residues may include remainders of a mask layer which was not entirely removed, remainders of a layer which was not completely etched away in a previously applied etching process, particles which may have attached to an underlying layer after or during a deposition process or other residues which may negatively affect the sample. According to embodiments described herein, such material residues may be identified, e.g. by inspecting the generated image.

The primary electron beam 20 may have an average electron energy of 10 keV or more, particularly 30 keV or more. In particular, the primary electron beam 20 may have an electron energy between 10 keV and 15 keV. The landing energy of the primary electron beam 20 on the sample may be 10 keV or more, particularly 30 keV or more. In particular, the landing energy may be between 10 keV and 15 keV.

As is schematically depicted in FIG. 1, the primary electron beam 20 is focused on the sample 10. The primary electron beam 20 may be generated by a beam source, shaped by electron optical elements arranged along a beam path, and focused by an objective lens (not shown in FIG. 1). The beam source may be operated such that the primary electron beam has an electron energy of 5 keV or more, particularly 10 keV or more, and/or 50 keV or less. The electron optical elements arranged along the beam path may be configured such that the primary electron beam impinges on the sample with a high electron energy of 5 keV or more, particularly 10 keV or more. In some embodiments, the beam source may be operated such that the primary electron beam has an electron energy below 5 keV, e.g. between 1 keV and 5 keV. Further, the primary electron beam may impinge on the sample with an electron energy up to 5 keV in some embodiments.

When the primary electron beam 20 hits the sample 10, a plurality of electrons are emitted from the sample, including secondary electrons 25 which are generated close to the sample surface and backscattered electrons which are scattered back from various layers of the sample. Typically, the secondary electron signal is substantially stronger than the backscattered electron signal. However, high-energy primary electrons may be backscattered from the sample with an increased probability. More specifically, the ratio between backscattered electrons and secondary electrons emitted from the sample may rise with an increasing energy of the primary electron beam.

According to some embodiments described herein, a filter device may be arranged between the sample 10 and the detector device 130 for filtering the signal electrons that are to be detected by the detector device 130. In particular, low-energy electrons, e.g. secondary electrons 25, may be suppressed by the filter device, and only higher-energy electrons including backscattered electrons may be allowed to proceed toward the detector device 130.

In particular, electrons emitted from the sample 10 having an electron energy below an energy threshold may be suppressed by the filter device which may be configured as a negatively biased filter electrode 154 arranged between the sample 10 and the detector device 130.

As is schematically depicted in FIG. 1, the filter electrode 154 may be provided above the sample 10 and may be configured to apply a repulsive force on electrons emitted by the sample. Low-energy electrons such as secondary electrons 25 may be deflected by the filter electrode 154 back toward the sample 10, whereas backscattered electrons having an energy above the energy threshold may propagate past the filter electrode 154 toward the detector device 130. The filter electrode 154 may be configured as a plate electrode having a hole or as a filter grid.

The filter electrode 154 may be set on a negative potential magnitude of, e.g. 50 V or more, such that only electrons with an electron energy above 50 eV can propagate toward the detector device 130. As is exemplarily depicted in FIG. 1, the first backscattered electrons 21 and the second backscattered electrons 22 can propagate past the filter electrode 154 toward the detector device 130, whereas the secondary electrons 25 are deflected back toward the sample 10.

The filter electrode 154 can be set on an adjustable variable electric potential which may be appropriate for filtering backscattered electrons reflected from a specific depth range of the multilevel structure 15. Two or more filter electrodes may be provided in some embodiments.

In a secondary electron detection mode, the filter electrode 154 may be set on an electric potential which may allow secondary electrons 25 to pass toward the detector device, e.g. electrons having an electron energy below 50 eV. For example, in the secondary electron detection mode, the filter electrode 154 may be set on a ground potential or on a positive potential. The secondary electrons may be detected by the detector device 130 or by a further detector device configured to detect secondary electrons. In the secondary electron detection mode, a topology of a surface of the sample can be inspected in detail. Accordingly, secondary electrons may be selectively gathered or suppressed.

In some embodiments, which may be combined with other embodiments described herein, the method described herein may include detecting the first backscattered electrons 21 and the second backscattered electrons 22 with an in-lens detector 136. An in-lens detector 136 may be understood as a detector device arranged at least partially around an optical axis of the primary electron beam 20. The in-lens detector 136 may include a detector opening 137 for the primary electron beam 20 to propagate therethrough. One or more detector segments of the in-lens detector may be arranged at least partially around the optical axis. For example, the in-lens detector may have an annular shape and extend partially or entirely around the optical axis. The electrons which are backscattered at small reflection angles of, e.g., between 1° and 30°, from the sample, can be detected by the in-lens detector 136.

The in-lens detector 136 may include a central opening to allow the primary electron beam 20 to propagate through the in-lens detector 136. Further, the in-lens detector 136 may subtend an azimuthal angle of at least a few degrees at the point of beam irradiation. Using a geometry such that the detector device subtends a large enough azimuthal angle at the point of impingement of the primary electron beam allows for the detection of a backscattered electron signal which is sufficiently strong to image also underlying layers quickly.

In further embodiments, other or additional types of detector devices may be provided.

The detector signal of the detector device 130 may be forwarded to a signal processing device 160 configured to process the detector signal, e.g. for generating an image of at least an area of the sample, or for performing defect identification or critical dimensioning.

The methods described herein allow for an in-line imaging of large area substrates for display manufacturing, wherein buried features which may span multiple layers (several nm up to 10 nm or more, tens of nm, or even many hundreds of nm) can be inspected. Such features can typically not be inspected by detecting secondary electrons which are generated within a few nanometers of the surface.

In some embodiments, the vacuum chamber of the apparatus 100 may be large enough to arrange and inspect the whole sample under vacuum conditions, for example downstream from the manufacturing of the multilayer structure in the same vacuum system. The detection of BSEs can be performed faster and more reliably under subatmospheric conditions because BSEs are scattered by air molecules and may not reach the detector device under atmospheric pressure. For example, the method described herein may be performed at a background pressure of less than 1 mbar, particularly less than 0.1 mbar. The pressure within a column of the electron microscope may be even less.

Imaging a sample 10 as described herein allows for an elemental contrast based on the atomic number of the materials of a plurality of layers of a multilevel structure. A distinction between different materials of a layer stack of a display device is possible. Said different materials may have similar secondary electron emission coefficients but widely varying BSE emission coefficients due to large differences in the atomic numbers of the respective materials.

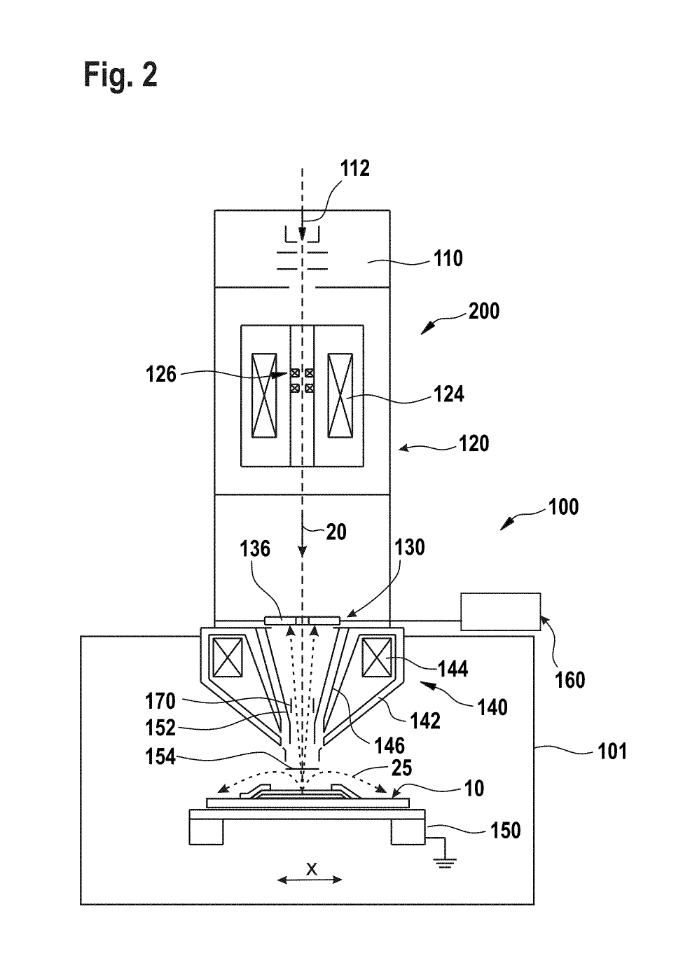

FIG. 2 is a schematic sectional view of an apparatus 100 for inspecting a sample 10 according to embodiments described herein. The apparatus is configured to be operated according to the methods described herein, and may be similar to the apparatus depicted in FIG. 1, such that reference can be made to the above explanations, which are not repeated here.

The apparatus 100 includes a vacuum chamber 101, wherein a sample support 150 configured to support the sample 10 is arranged in the vacuum chamber 101. The sample support 150 may be configured to support a large area substrate for display manufacturing, particularly having a size of 1 m² or more, particularly 5 m² or more, more particularly 10 m² or more.

The apparatus 100 further includes an electron microscope 200 configured to direct a primary electron beam 20 toward the sample 10 such that first primary electrons of the primary electron beam 20 are backscattered by a first layer of the sample to form first backscattered electrons and second primary electrons are backscattered by the second layer of the sample to form second backscattered electrons.

The sample support 150 may extend along an x-direction. The sample support 150 may be movable along the x-direction to displace the sample 10 in the vacuum chamber 101 relative to the electron microscope 200. Accordingly, an area of the sample 10 can be positioned below the electron microscope 200 for inspection. The area may contain a multi-level structure, e.g. a multi-layer electronic device to be inspected having, e.g., a grain or defect contained in layer on the sample. The sample support 150 may optionally also be movable along a y-direction so that the sample 10 can be moved along the y-direction which may be perpendicular to the x-direction. By suitably displacing the sample support 150 holding the sample 10 within the vacuum chamber 101, the entire extent of the sample 10 may be inspected inside the vacuum chamber 101.

The electron microscope 200 may include an electron source 112 configured to generate the primary electron beam 20. The electron source 112 may be an electron gun configured to generate a primary electron beam having an electron energy of up to 5 keV, 5 keV or more, particularly 10 keV or more, more particularly 15 keV or more. Within a gun chamber 110, further beam shaping devices like a suppressor, an extractor and/or an anode may be provided. The beam may be aligned to a beam limiting aperture which may be dimensioned to shape the beam, i.e. blocks a portion of the beam. The electron beam source can include a TFE emitter. The gun chamber 110 may be evacuated to a pressure of 10⁻⁸ mbar to 10⁻¹⁰ mbar.

The electron microscope 200 may further include a column 120, wherein the primary electron beam 20 propagates through the column 120 along an optical axis. Electron optical elements 126 may be arranged in the column 120 along the optical axis, wherein the electron optical elements 126 may be configured to collimate, shape, deflect, and/or correct the primary electron beam 20. For example, a condenser lens may be provided in the column 120. The condenser lens can include a pole piece and a coil 124. Further electron optical elements may be provided selected from the group consisting of a stigmator, correction elements for chromatic and/or spherical aberrations, and alignment deflectors for aligning the primary electron beam to an optical axis of the objective lens 140.

An objective lens 140 may be provided for focusing the primary electron beam 20 onto the sample 10 with a landing energy of up to 5 keV or 5 keV or more, particularly 10 keV or more, more particularly 15 keV or more.

As is shown in FIG. 2, the objective lens 140 may have a magnetic lens component having pole pieces 142 and 146, and having a coil 144. Optionally, an upper electrode 152 may form an electrostatic lens component of the objective lens 140.

Further, a scanning deflector assembly 170 can be provided. The scanning deflector assembly 170 can, for example, be a magnetic, but also an electrostatic scanning deflector assembly. The scanning deflector assembly 170 may be a single stage assembly, as shown in FIG. 2. Alternatively, a two-stage or even a three-stage deflector assembly can be provided for scanning. Each stage may be provided at a different position along the optical axis.

The electron microscope 200 further includes a detector device 130 configured to detect signal electrons including the first backscattered electrons and the second backscattered electrons. The detector signal may be supplied to a signal processing device 160 configured to generate an image which contains spatial information on both the first layer and the second layer based on the detector signal.

The electron microscope 200 may further include a filter electrode 154 arranged between the sample support 150 and the detector device 130, e.g. at a short distance above the sample support 150. The filter electrode 154 may be configured to suppress low-energy electrons, particularly secondary electrons. For example, the filter electrode 154 may suppress electrons emitted from the sample 10 which have an electron energy below a threshold energy of, e.g., 50 eV. Further, the filter electrode 154 may be configured to allow signal electrons with an electron energy above the energy threshold to pass toward the detector device 130.

In particular, signal electrons including the first backscattered electrons and the second backscattered electrons may propagate past the filter electrode 154 toward the detector device 130. In some embodiments, the filter electrode 154 is configured to be set on a negative potential, wherein the negative potential may be, for example, greater than 50V to suppress secondary electrons and to allow backscattered electrons to pass.

In some embodiments, which may be combined with other embodiments described herein, the detector device may include an in-lens detector 136 with an opening for the primary electron beam 20. The in-lens detector 136 may be adapted to detect signal electrons having an energy of 50 eV or more. In particular, the in-lens detector 136 may be adapted to detect backscattered electrons having an energy of 1 keV or more.

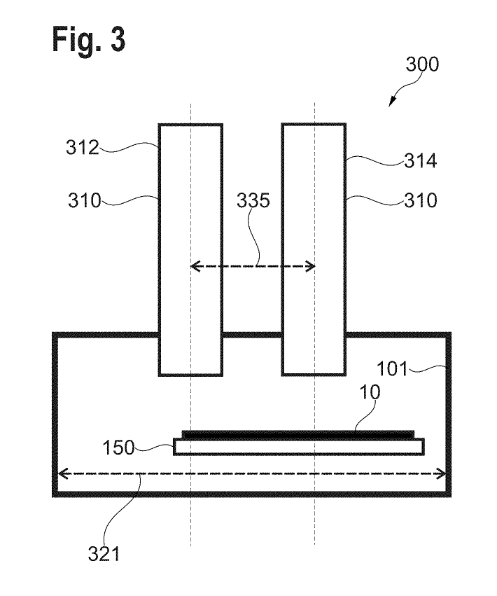

FIG. 3 is a schematic sectional view of an apparatus 300 for inspecting a sample 10 according to embodiments described herein. The apparatus 300 includes a vacuum chamber 101 and a sample support 150 arranged in the vacuum chamber 101 for supporting the sample 10. The vacuum chamber 101 may be similar to the vacuum chamber depicted in FIG. 2, such that reference can be made to the above explanations.

Further, the apparatus 300 includes a plurality of electron microscopes 310 for a simultaneous inspection of a plurality of areas of the sample 10. Two electron microscopes 310, i.e. a first electron microscope 312 and a second electron microscope 314, are exemplarily depicted in FIG. 3. In some embodiments three or more electron microscopes may be provided for inspecting respective areas of the sample 10. The electron microscopes may be similar to the electron microscope 200 of FIG. 2, such that reference can be made to the above explanations, which are not repeated here.

In particular, each electron microscope of the plurality of electron microscopes 310 may be configured to direct a primary electron beam toward the sample 10 such that first primary electrons of the primary electron beam are backscattered by the first layer as first backscattered electrons and second primary electrons are backscattered by the second layer as second backscattered electrons. The electron microscopes may include a respective detector device configured to detect signal electrons including the respective first backscattered electrons and second backscattered electrons.

A signal processing device may be provided to generate an image including information on both the first layer and the second layer. In some embodiments, each electron microscope includes a respective signal processing device. In other embodiments, the detector signals of the plurality of electron microscopes 310 may be supplied to a common signal processing device which may be configured to generate an image of a plurality of areas of the sample imaged by the plurality of electron microscopes 310. The image provides spatial information on both the first layer and the second layer of the sample 10.

The first electron microscope 312 may be distanced from the second electron microscope 314 along the x-direction by a distance 335. In the embodiment illustrated in FIG. 3, the distance 335 is a distance between a first optical axis of the first electron microscope 312 and a second optical axis of the second electron microscope 314. As is further shown in FIG. 3, the vacuum chamber 101 has an inner width 321 along the x-direction. According to embodiments, the distance 335 along the x-direction between the first electron microscope 312 and the second electron microscope 314 may be at least 30 cm, such as at least 40 cm. According to further embodiments, which can be combined with other embodiments described herein, the inner width 321 of the vacuum chamber 101 may lie in the range from 250% to 450% of the distance 335 between the first electron microscope 312 and the second electron microscope 314.

Embodiments described herein thus provide an apparatus for inspecting a sample, in particular including a large area substrate, in a vacuum chamber 101 using two or more electron microscopes distanced from each other. An increased throughput compared to embodiments having a single electron microscope can be provided, since the sample may be inspected in parallel by two or more electron microscopes. For example, a first defect on the sample may be inspected by the first electron microscope 312 and a second defect of the sample may be inspected by the second electron microscope, wherein the inspection of the first defect and the second defect are carried out in parallel.

According to some embodiments, which can be combined with other embodiments described herein, an electron microscope can be a scanning electron microscope (SEM), wherein an image is provided with a very high resolution, e.g. of 1 to 20 nm depending on the measurement conditions.

According to some implementations, the apparatus for inspecting the sample can be an in-line apparatus, i.e. the apparatus, potentially including a load lock for loading and unloading the sample in the vacuum chamber for imaging, can be provided in line with further manufacturing, testing or processing devices. The vacuum chamber may include one or more valves, which may connect the vacuum chamber to another chamber, in particular if the apparatus is an inline apparatus. After a sample has been guided into the vacuum chamber, the one or more valves can be closed. Accordingly, the atmosphere in the vacuum chamber can be controlled by generating a technical vacuum, for example, with one or more vacuum pumps.

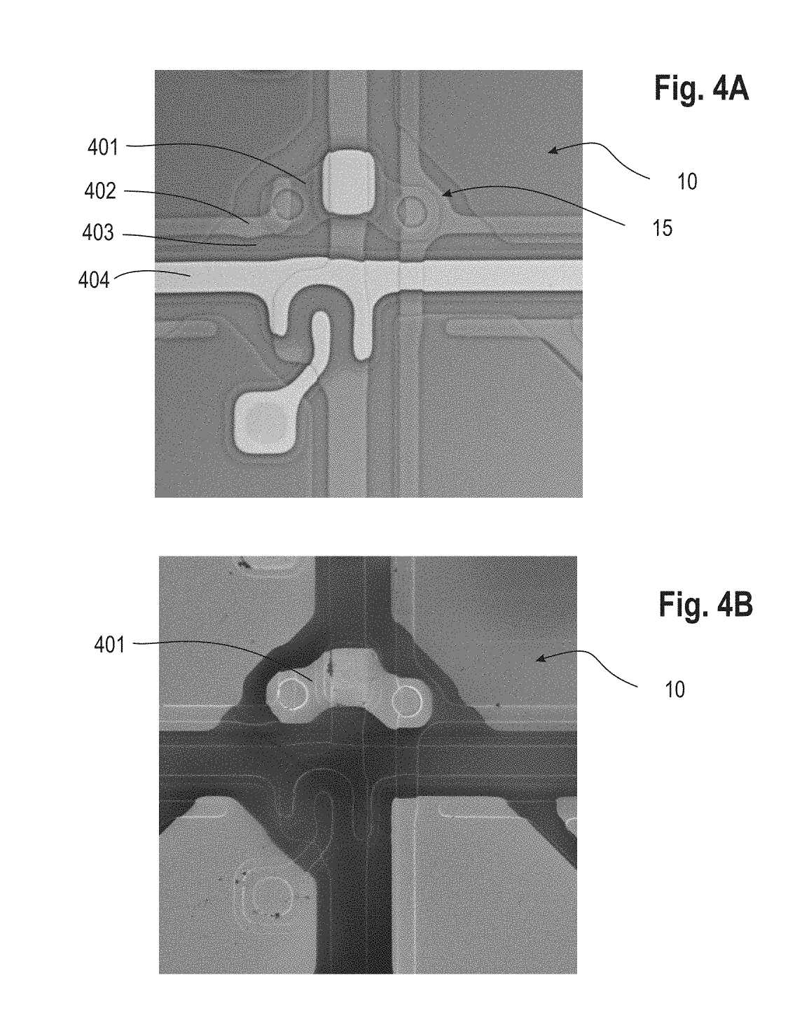

FIG. 4A shows an image of a sample 10 generated according to a method described herein. FIG. 4B shows an image of the same sample generated according to a conventional method.

The sample 10 includes a multilevel structure 15 with a plurality of layers which are at least partially arranged on top of each other. The layers may include materials having different atomic numbers, such that the capabilities of the layers to backscatter electrons may be different. For example, the multilevel structure 15 may include a first layer 401 including a first material which may be a top layer of the multilevel structure 15. The multilevel structure may further include a second layer 402 including a second material, a third layer 403 including a third material, and a fourth layer 404 including a fourth material arranged below the first layer 401.

In some embodiments, the multilevel structure 15 may constitute an electronic device deposited on a substrate. At least one layer may be a metal layer providing conductive paths or via, at least one layer may be a conductive layer providing an electrode, e.g. a gate region, a source region or a drain region, at least one layer may be a dielectric layer, at least one layer may be a passivation layer, and/or at least one layer may be a semiconductor layer.

When the primary electron beam having preset beam properties impinges on the sample 10, first electrons of the primary electron beam are backscattered by the first layer 401 to form first backscattered electrons, second electrons of the primary electron beam are at the same time backscattered by the second layer 402 to form second backscattered electrons, third electrons of the primary electron beam are backscattered by the third layer 403 to form third backscattered electrons, and fourth electrons of the primary electron beam are backscattered from the fourth layer 404 to form fourth backscattered electrons. The image depicted in FIG. 4A may be generated based on said backscattered signal electrons.

As can be clearly seen from FIG. 4A, spatial information on each of the first to fourth layers can be obtained from the detected backscattered signal electrons. In particular, the edge regions of the layers can be inspected to perform overlay metrology, dimensions of buried layers can be measured, material residues which may be hidden below an upper layer may be identified, and/or defects of buried layers can be reviewed or analyzed.

FIG. 4B is a comparative example of an image generated according to conventional methods, including the predominant detection and processing of secondary electrons (SEs). As is clearly depicted in FIG. 4B, essentially only the first layer 401 is visible from the generated image such that it is not possible to inspect any of the buried layers of the sample 10. Furthermore, no information relating to the type of materials and especially relating to the atomic number of the atoms in the sample investigated can be identified in the comparative example of FIG. 4B.

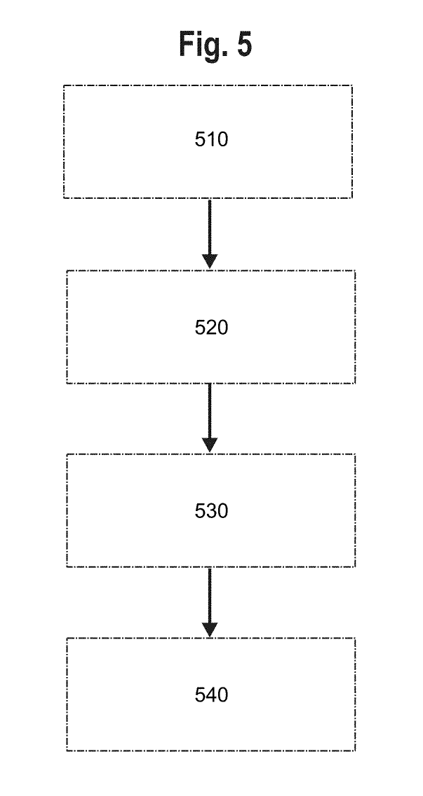

FIG. 5 is a flow diagram illustrating a method of inspecting a sample according to embodiments described herein. The sample includes a multilevel structure with a stack of features arranged at least partially on top of each other, including a first layer 11 that is arranged above a second layer 12.

In box 510, the sample 10 is arranged in a vacuum chamber under subatmospheric pressure. For example, the sample is arranged on a sample support in the vacuum chamber such that a primary electron beam of an electron microscope can be directed toward an area of the substrate.

In box 520, a primary electron beam 20 is directed onto the sample such that first primary electrons of the primary electron beam are backscattered by the first layer 11 to form first backscattered electrons 21 and, at the same time, second primary electrons of the primary electron beam are backscattered by the second layer 12 to form second backscattered electrons 22.

In box 530, signal electrons emitted from the sample and including the first backscattered electrons 21 and the second backscattered electrons 22 are detected by a detector device for obtaining spatial information on both the first layer 11 and the second layer 12, particularly in a single-stage acquisition process. An area of the sample may be scanned while the signal electrons are being detected by the detector device.

In optional box 540, an image of at least an area of the sample is generated by a signal processing device based on the detector signal. The image provides spatial information on both the first layer and the second layer, and optionally further layers of the multilevel structure.

In some embodiments, a defect review or a measurement and inspection of dimensions of the multilayer structure may follow. In particular, an overlay metrology may be conducted.

While the foregoing is directed to some embodiments, other and further embodiments may be devised without departing from the basic scope thereof, and the scope thereof is determined by the claims that follow.

1. A method of inspecting a sample, the sample including a large-area substrate for display manufacturing with a size of at least 1 m² and having a multilevel structure with a first layer that is arranged above a second layer, the method comprising:
arranging the sample in a vacuum chamber;
directing a primary electron beam onto the sample such that first primary electrons of the primary electron beam are backscattered by the first layer to form first backscattered electrons and second primary electrons of the primary electron beam are backscattered by the second layer to form second backscattered electrons; and
simultaneously detecting signal electrons comprising the first backscattered electrons and the second backscattered electrons for obtaining spatial information on both the first layer and the second layer, wherein the multilevel structure contains a passivation layer, and at least one of the first layer and the second layer is arranged below the passivation layer.

2. The method of claim 1, further comprising at least one of:
generating an image of the multilevel structure based on the detected signal electrons;
inspecting the first layer and the second layer;
reviewing, analyzing or identifying defects of at least one of the first layer and the second layer;
measuring distances or dimensions of at least one of the first layer and the second layer; and
performing an overlay metrology.

3. The method of claim 1, wherein the multilevel structure has three or more layers arranged at least partially on top of each other, wherein respective primary electrons of the primary electron beam are scattered by each of the three or more layers and subsequently detected for obtaining spatial information on each of the three or more layers.

4. (canceled)

5. The method of claim 1, wherein the multilevel structure comprises a plurality of multilevel electronic or optoelectronic devices.

6. The method of claim 1, wherein the multilevel structure comprises multilevel features with nonlinear or curved edges, wherein the nonlinear or curved edges are imaged or inspected.

7. (canceled)

8. The method of claim 1, wherein the first layer comprises a first material having a first atomic number with a first electron backscattering capability, and the second layer comprises a second material having a second atomic number with a second electron backscattering capability, the method further comprising:
generating an image based on the detected signal electrons, wherein holes, openings, steps, recesses, overlaps and/or undercuts of at least one of the first layer and the second layer appear as regions of specific brightness in the image, respectively.

9. The method of claim 1, wherein the primary electron beam impinges on the sample with a landing energy of 5 keV or more.

10. The method of claim 1, wherein the first layer comprises a first material having a first atomic number, and wherein material residues comprising a second material having a second atomic number arranged below the first layer are identified.

11. The method of claim 1, comprising scanning an area of the sample one single time with the primary electron beam, and generating an image of said area based on the signal electrons detected during the scanning.

12. The method of claim 1, further comprising suppressing electrons emitted from the sample having an electron energy below an energy threshold.

13. The method of claim 1, comprising detecting the first backscattered electrons and the second backscattered electrons with an in-lens detector comprising a detector opening for guiding the primary electron beam therethrough.

14.-20. (canceled)
